(19) United States
(12) Patent Application Publication
(10) Pub. No.: US 2009/0011577 A1
(43) Pub. Date: Jan. 8, 2009

(54) METHOD OF MAKING PHASE CHANGE MATERIALS ELECTROCHEMICAL ATOMIC LAYER DEPOSITION

(75) Inventors: Qiang Huang, Ossining, NY (US); Xiaoyan Shao, Yorktown Heights, NY (US); John L. Stickney, Athens, GA (US); Venkatram Venkatasamy, Athens, GA (US)

Correspondence Address: CONNOLLY BOVE LODGE & HUTZ LLP, 1875 EYE STREET, N.W., SUITE 1100, WASHINGTON, DC, 20006, US

(73) Assignee: IBM CORPORATION (YORKTOWN), Yorktown Heights, NY (US)

(21) Appl. No.: 11/774,105

(22) Filed: Jul. 6, 2007

(51) Int. Cl. H01L 21/20

(52) U.S. Cl. 438/488; 257/E21.09

(57) ABSTRACT

A method of making phase change materials on a substrate by electrochemical atomic layer deposition, which includes sequentially electrodepositing at least one atomic layer of a first element of a first solution and at least one atomic layer of a second element of a second solution on a substrate; and repeating the sequential electrodepositing until at least one film of a phase change material is formed on the substrate.

### BACKGROUND

1. Technical Field

The disclosure relates to a method of making a phase change material (PCM) by electrochemical atomic layer deposition (EC-ALD) on a conductive substrates, especially on metallic substrates such as Au, W, Cu, Ni, Co, and conductive nitride substrate such as TN, WN, and TaN for memory or electronic storage devices. In particular, the method includes sequentially electrodepositing atomic layers on the substrates, and repeating the sequential electrodepositing until at least one film of PCMs are formed on the substrates. The EC-ALD of PCMs results in better crystallinity of films for memory or electronic storage applications, such that volume shrinkage and the formation of the voids in the films are eliminated.

2. Discussion of the Background

Memory or electronic storage has always been one of the important areas of constant research and development. Memory can be of two kinds: volatile and nonvolatile, based upon the retainment of information in the presence or absence of external power supply. A nonvolatile memory is the storage media that retains stored information even in the absence of external power and the opposite holds true for the volatile memory.

Phase change memory (PCM) is one of the most promising candidates for next-generation nonvolatile memory devices. It utilizes the unique property of phase transition between amorphous and crystalline states of chalcogenide based materials. The properties of chalcogenide glasses were first explored as a potential memory technology by Stanford Ovshinsky of Energy Conversion Devices in the 1960s.

The crystalline and amorphous states of chalcogenide glass have dramatically different electrical resistivity values, and this forms the basis by which data is stored. The amorphous, high resistance state is used to represent a binary 1, and the crystalline, low resistance state represents a 0. Chalcogenide is also utilized in re-writable optical storage media (such as CD-RW and DVD-RW). In those instances, the material's optical properties are manipulated, rather than its electrical resistivity, as chalcogenide's refractive index also changes with the state of the material.

Fast and reversible structural phase transformations in chalcogenide Ge—Sb—Te (GST) glasses, which underlie current technology, focus on their uses in rewritable optical media as well as in non-volatile electrically-controlled memory cells. The conversion from a highly resistive amorphous to a highly conducting (metallic) phase is attained by appropriate heating and cooling of the material (either by a laser or a current/voltage pulse). It can be programmed reversibly on a timescale of nanoseconds provided that the transforming volume is sufficiently small. This switching can be fast because the crystallization-amorphorization process appears not to rupture strong covalent bonds, ideally ensuring that the phase change is easily reversed over many cycles.

At present, the PCMs, especially GST, are laid down by a variety of physical methods like sputtering, thermal evaporation, pulsed laser deposition, chemical vapor deposition and metal organic chemical vapor deposition, etc. To fill up the GST alloys in trench structures with a high aspect ratio is an issue for these methods. Not only is there poor conformal coverage, but such methods result in the deposits being amorphous. Hence, an extra step of thermal annealing is included in the integration process to crystallize the GST material. It also is a well known phenomenon that on crystallization, the material undergoes considerable volume shrinkage which creates reliability issue due to the formation of voids.

Electrodeposition of PCMs is much in need to satisfy the requirements in filling trenches. However, the main challenge of electrodeposition of PCMs is the difficulty in codepositing Ge from an aqueous solution, where Ge serves as a key component to obtain high enough crystallization temperature for reliable information storage. In addition, traditional electrodeposition often produces amorphous film for these materials, where the problematic volume shrinkage in the existing methods retains.

Crystalline films can be electrodeposited by using electrochemical atomic layer deposition (EC-ALD). EC-ALD is the electrochemical analog of atomic layer epitaxy (ALE) and atomic layer deposition (ALD), in which these methods are based on the use of surface limited reactions to form deposits in a layer-by-layer fashion. The advantages of these methodologies are that they can be used to control the deposition at atomic level and form crystalline materials. However, conventional work with EC-ALD has merely involved electrodeposition of nanoflims of compound semiconductors, including II-VI compounds, such as CdTe, CdS and ZnSe, as well as some III-V compounds, such as GaAs, InAs, and InSb. PbSe, PbTe and Bi₂Te₃.

Thus, there remains a need for method of successfully depositing and forming PCM materials, including but not limited to, Sb₂Te₃, InSbTe, AgSbTe GeSb, and GeSbTe, by EC-ALD, which minimizes or eliminates the volume shrinkage, void formation, and lack of conformal coverage problems of conventional physical and chemical methods.

### SUMMARY

Accordingly, the following embodiments provide a method of making a phase change material (PCM) by electrochemical atomic layer deposition (EC-ALD) on a substrate. In particular, in one embodiment, the method comprises:

sequentially electrodepositing at least one atomic monolayer or submonolayer of a first element of a first solution and at least one atomic monolayer or submonolayer of a second element of a second solution on a substrate; and

repeating the sequential electrodepositing until at least one film of a phase change material is formed on the substrate.

In another embodiment, the EC-ALD is successfully employed towards the specific formation of PCMs that include, but are not limited to, Sb₂Te₃, InSbTe, InAgSbTe, GeSbTe, and GeSb on Au and TiN substrates. Successful via filling is demonstrated by growing PCMs, such as Sb₂Te₃, on patterned TiN wafers, as shown and described in the experimental examples described below.

The above aspects highlight certain embodiments of the EC-ALD method. However, additional aspects and advantages will be become readily apparent by those skilled in the art by the following description of the drawings and detailed description of the disclosure.

### BRIEF DESCRIPTION OF THE DRAWINGS

FIG. 1 illustrates a flow deposition system used for the formation of PCM films.

FIG. 2 shows a cyclic voltammetry of Sb on Au.

FIG. 3 shows a cyclic voltammetry of Te on Au.

FIG. 4 is a graphic representation of the optimal ALD cycle to deposit Sb₂Te₃ on Au.

FIG. 5 shows a XRD analysis of a deposit Sb₂Te₃ on Au.

FIG. 6 shows a cyclic voltammetry scan of Te deposition on TiN.

FIG. 7 shows a cyclic voltammetry scan of Sb deposition on TiN, in which no UPD feature was observed and deposition took place by nucleation and growth phenomenon.

FIG. 8 shows the UPD feature of Sb deposition on a Te covered surface.

FIG. 9 shows the optimal deposition cycle to form Sb₂Te₃ on TiN.

FIG. 10 shows a XRD analysis of a deposit Sb₂Te₃ on TiN.

FIG. 11 shows a SEM image of a 40 cycle PCM deposit on SiO₂ patterned TiN surface.

FIG. 12 shows the cycle for depositing InTe.

FIG. 13 is a graphic representation of the optimal ALD cycle to deposit AgSbTe.

FIG. 14 shows a cyclic voltammetry scan of Ge under-potential-deposition (UPD) on Au.

FIG. 15 shows cyclic voltammetry scans of Ge UPD on Te, Au, and Sb.

### BEST AND VARIOUS MODES FOR CARRYING OUT DISCLOSURE

A more complete appreciation of the disclosure and many of the attendant advantages will be readily obtained, as the same becomes better understood by reference to the following detailed description when considered in connection with the accompanying drawings.

It should be understood that voltage values (V) in the disclosure in accordance with a Ag/AgCl reference electrode. It should also be understood that the voltage value may be shifted by a fixed difference if a different reference electrode is used.

In electrochemical studies, surface limited reactions are generally referred to as under potential deposition (UPD). UPD is a phenomenon wherein one element electrodeposits on another, at a potential prior to (under) the potential at which the first element deposits on to itself, as generally described in U.S. Pat. No. 5,320,736. As discussed above, electrochemical atomic layer deposition (EC-ALD) generally involves the sequential electrodeposition of atomic layers of elements to form nanofilms of materials using underpotentials. In particular, EC-ALD involves the use of surface limited reactions to form deposits with atomic layer control.

In the EC-ALD method of the disclosure, the phase change material (PCM) is generally polycrystalline or single crystalline and may have a superlattice structure. In forming the structure of the PCM, the first element of the first solution deposited may be selected from the group consisting of germanium (GE), antimony (Sb), indium (In), and silver (Ag). The second element of the second solution deposited may be selected from the group consisting of antimony and tellurium (Te). In addition, at least one atomic monolayer of a third element of a third solution may also be electrodeposited on the substrate to form the PCM, in which the third element includes, but is not limited to, tellurium. As such, the PCM may include, but is not limited to, Sb₂Te₃, InSbTe, AgSbTe, GeSb, and GeSbTe, and combinations thereof.

The first, second, and third elements for each of the solutions are also selected based on a deposition potential (UPD potential) for the elements. The deposition potential for Sb may range from about −0.3 V to about 0.1 V. The deposition potential for Te may range from about −0.7 V to about 0.4 V. The deposition potential for Ge may range from about −0.5 V to about 0.1 V. The deposition potential for In may range from about −0.5 V to about 0.0 V. The deposition potential for Ag may range from about 0.1 V to about 0.5 V.

During the EC-ALD, monolayers or submonolayers of the elements are electrodeposited at room temperature, or may be deposited in a temperature range from about 0° C. to about 90° C. The monolayer or submonolayer may range in thickness from about 1 Å to about 10 Å. The sequential formation of each monolayer or submonolayer results in the formation of the PCM film, in which from about 10 to about 100,000 layers of the PCM may be formed on a substrate.

The substrate used for the EC-ALD may include, but is not limited to, any conductive substrate useful for memory or electronic storage applications, which may include an electrode or a wafer. In particular, the substrate may be a conductive metal material, semiconductors, or an alloy material. Preferably, the substrate is gold or titanium nitride.

### EXAMPLES

The following non-limiting experimental examples are presented to further illustrate the formation of PCM films and the EC-ALD method of the disclosure.

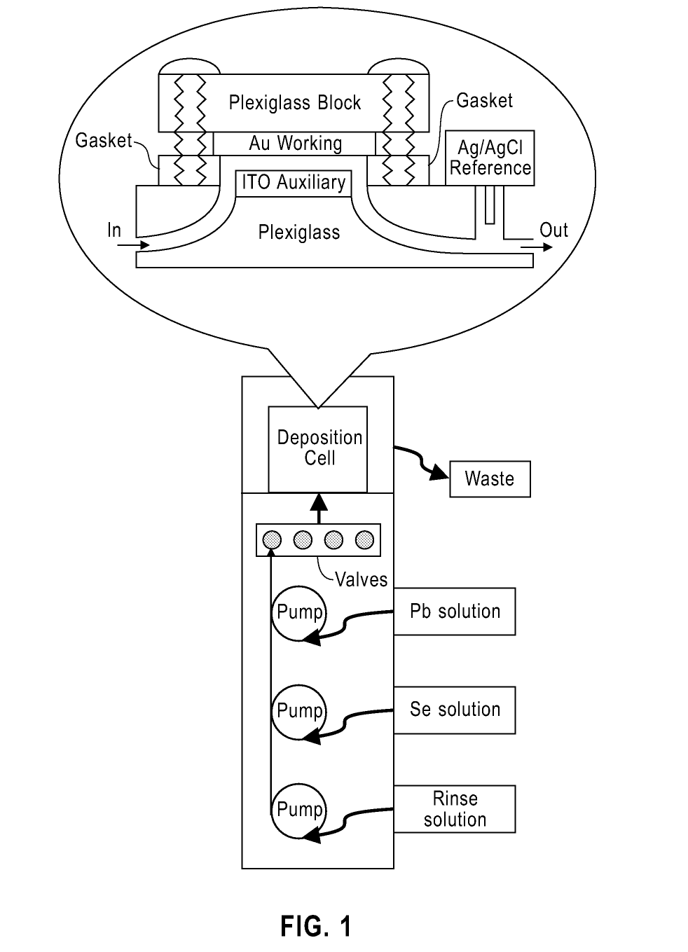

The flow deposition system used for the formation of PCM films consisted of peristaltic pumps, a solenoid selection valve and a flow cell, as shown in FIG. 1. The tubing was kept inside a nitrogen purged Plexiglas box, to cut down on oxygen issues. The electrochemical flow cell was of a laminar flow over design. The auxiliary electrode (ITO, Pt, or platinized Ti) and the working electrode were held apart by a silicon rubber gasket, which defined the opening area for deposition. The reference electrode was positioned at the cavity outlet.

The solutions used consisted of 1 mM GeO₂ (pH 1.4), 0.2 mM TeO₂ (pH 4), 0.2 mM Sb₂O₃ (pH 1.4), 1 mM Ag₂SO₄ (pH 1.4), all made with 0.5M Na₂SO₄ as supporting electrolyte. 0.5 mM In₂(SO₄)₃ solution (pH 5) was made with 0.5 M CH₃COONa as supporting electrolyte. The blank solution contained 0.5 M Na₂SO₄ (pH 4). The solution pH was adjusted using H₂SO₄. The gold substrates used for the initial experiments consisted of 200 nm Au sputtered on 30 nm Ti clad Si (100) wafers. The other substrates that were used were 200 nm PVD TiN on Si and patterned TiN wafers with 200 nm openings within silicon oxide.

It should be understood that the design of the method was first to identify the UPD potentials of the constituent elements by cyclic voltammetry on a Au or TiN electrode, and then to create an ALD cycle using the potentials obtained. The following experiments exemplify depositions of PCMs of the disclosure, in view of the above described flow deposition system and solutions.

### Deposition of Sb₂Te₃ on Au and TiN

Sb₂Te₃ is an important compound in the family of PCM materials. Hence, the deposition of Sb₂Te₃ was undertaken as the first part of the first experiment.

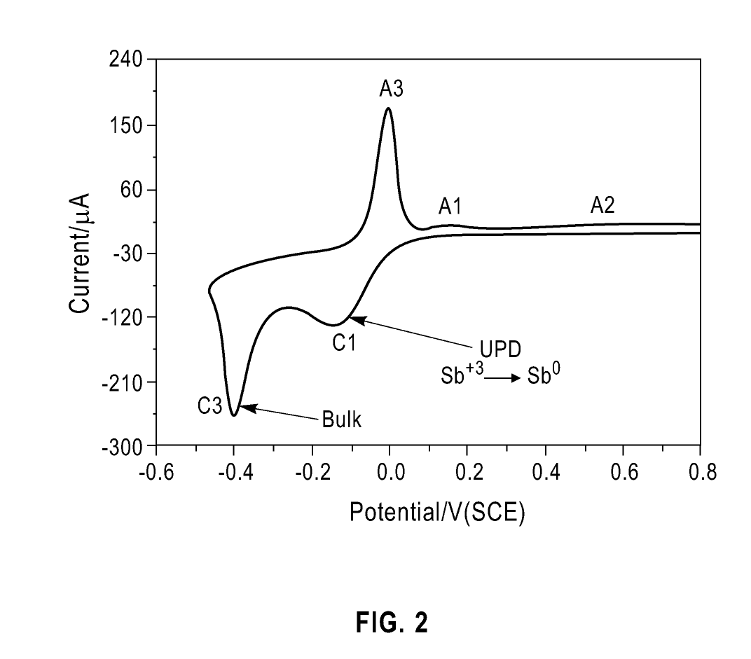

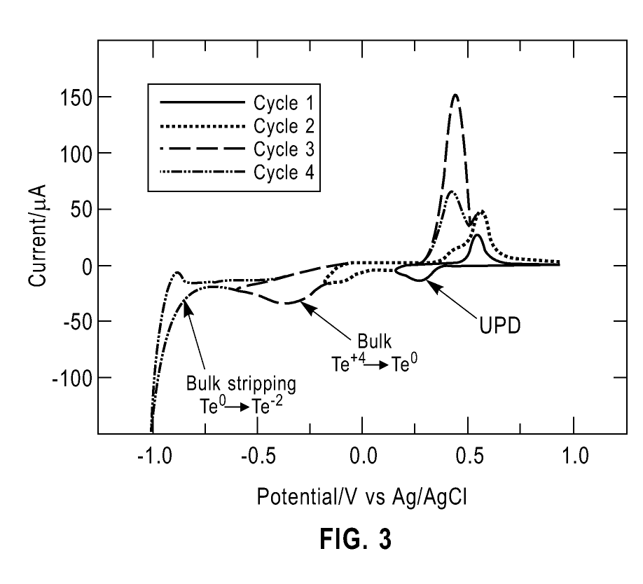

FIGS. 2 and 3 show the cyclic voltammetries of Sb and Te on Au respectively. The UPD potentials were found out to be about −0.20 V for Sb and −0.35 V for Te. Since Te does not have a true UPD due to slow deposition kinetics, Te is deposited in the bulk region and the excess Te deposited is removed with a bulk reduction step. It is the step where the potential is shifted negative such that only the excess Te gets reduced into a soluble telluride species, leaving only an atomic layer of Te.

In order to find the ideal deposition potential for Sb, a series of deposits were made where the Te deposition and stripping steps were kept constant at −0.35 V and −0.70 V respectively, while changing the Sb deposition potentials from −0.17 V to −0.30 V. All of the deposits were made of 100 deposition cycles, in which one cycle is defined as the following: the Te solution was flushed into the cell for 2 s (30 mL/min), and held quiescent for 15 s at the potential chosen for Te deposition.

A blank solution was then flushed through the cell for 3 s. Any excess Te was then removed by flushing the cell with the blank, and holding at −0.70 V, which served to reduce any bulk Te to telluride ions, which were then flushed from the cell with 3 second blank rinse followed by filling the cell with the Sb solution for 2 s, and holding quiescent for 15 s, for deposition. The cycle was completed by flushing with the blank for 3 s.

The resulting deposits were analyzed for composition by electron probe microanalysis (EPMA).

Table 1, as illustrated below, shows the effect of the Sb deposition potential on the deposit composition.

| | Te red | | Sb | Te | |
|---|---|---|---|---|---|
| Te (V) | (V) | Sb (V) | (ML vs Au) | (ML vs Au) | Te/Sb |
| −0.35 | −0.70 | −0.17 | 0.14 | 0.37 | 2.1 |
| −0.35 | −0.70 | −0.20 | 0.31 | 0.41 | 1.7 |
| −0.35 | −0.70 | −0.22 | 0.26 | 0.36 | 1.5 |
| −0.35 | −0.70 | −0.25 | 1.07 | 0.43 | 0.3 |
| −0.35 | −0.70 | −0.30 | 1.30 | 0.33 | 0.1 |

In particular, it was observed that as the deposition potential of Sb was shifted negative, the Sb coverage based on charge also increases as expected. The ideal deposition potential for Sb on Au was found to be −0.22 V.

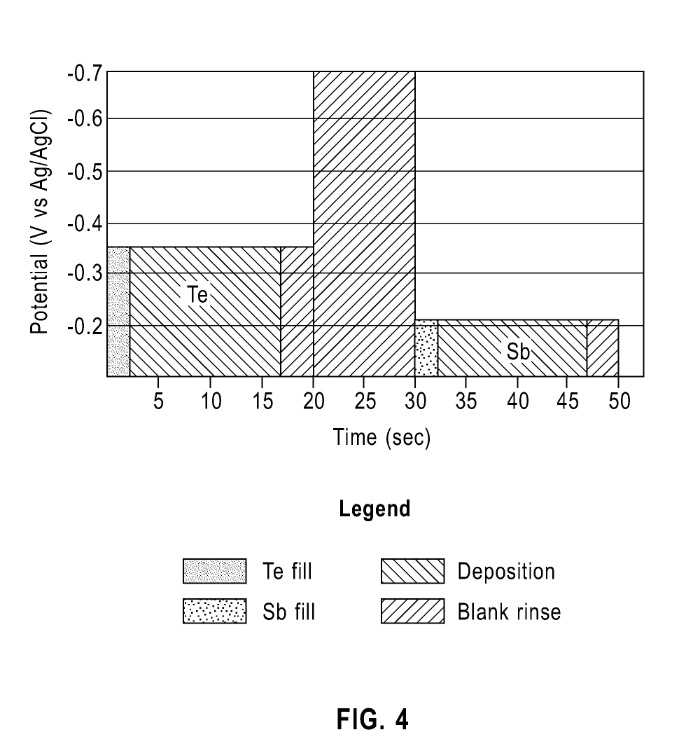

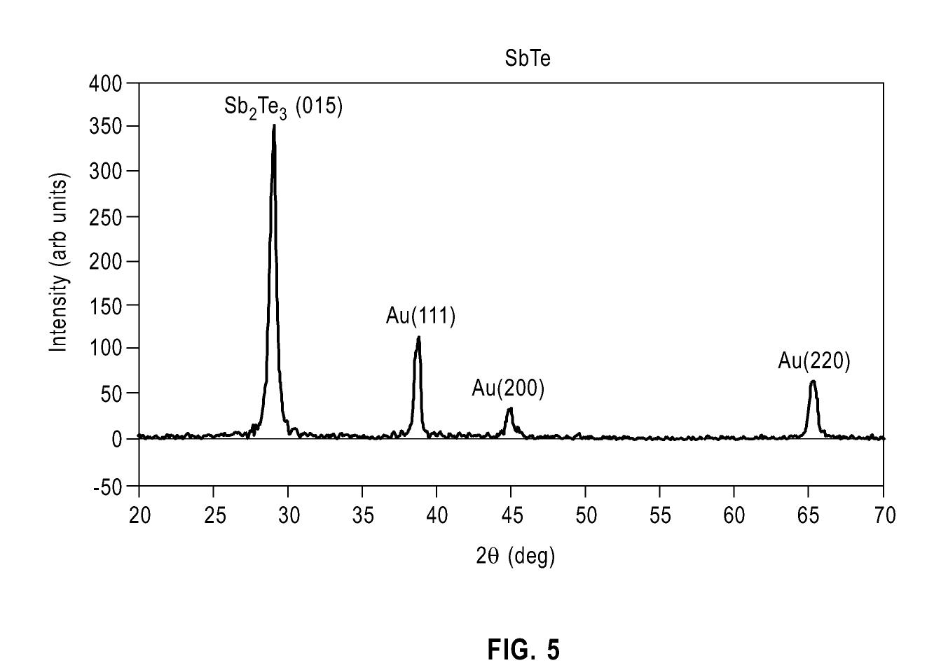

FIG. 4 is a representation of an optimal ALD cycle to deposit Sb₂Te₃ on Au. In the cycle, the Te solution was fed into the cell for 2 seconds at a potential of −0.35 V, the Te solution was held for another 15 seconds while the potential maintained at −0.35 V, the cell was flushed with the blank solution for 3 seconds with potential at −0.35 V, the cell was flushed with the blank solution for another 10 seconds with potential at −0.70 V, the Sb solution was fed into the cell for 2 seconds at −0.22 V, the Sb solution was held while the potential held at −0.22V for another 15 seconds, and then the cell was flushed with blank solution at −0.22 V for 3 seconds to finish a cycle. The same cycle was repeated for 100 times to obtain a Sb₂Te₃ film of about 50 nm. Glancing incidence XRD analysis of this deposit (FIG. 5) showed the deposit to be highly textured crystalline with a sharp (015) peak of Sb₂Te₃.

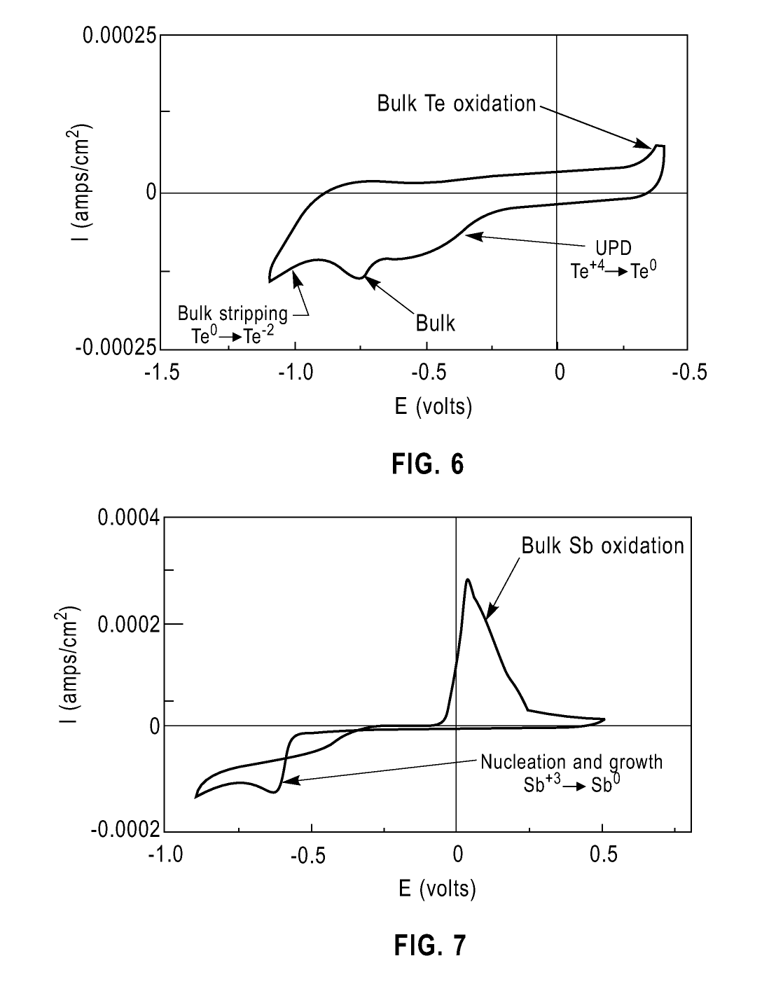

During EC-ALD of PCM on a TiN substrate, the electrode was pretreated with DHF (1:10) rinse for 10 s to get rid of TiOx, and then the Te solution was flown into the cell to start deposition. FIG. 6 shows the cyclic voltammetry scan of Te on TiN, which suggested that TiN is a good substrate for Te deposition.

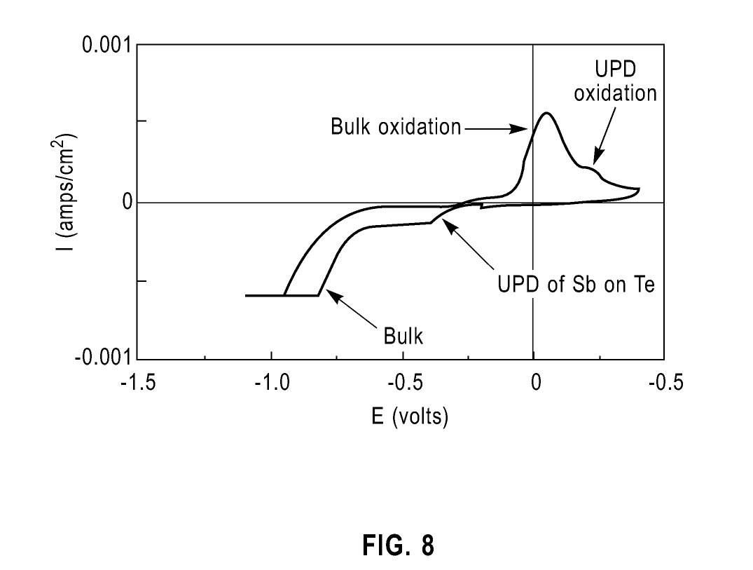

The same approach was taken to assess Sb deposition on TiN. In this case, no UPD feature was observed and deposition took place by nucleation and growth phenomenon (FIG. 7). This is undesirable when trying to grow a compound in a layer by layer fashion. A cyclic voltammetry was performed of Sb on Te coated TiN. This time, the UPD feature of Sb deposition was observed (FIG. 8) and there was no indication of any nucleation and growth process. The cyclic voltammograms indicated that a layer by layer growth approach of Sb₂Te₃ was possible on TiN.

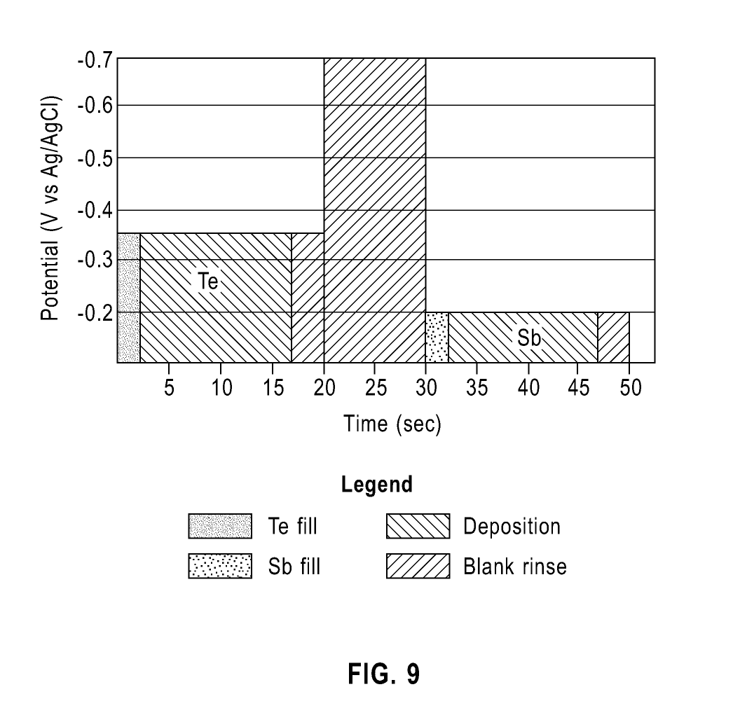

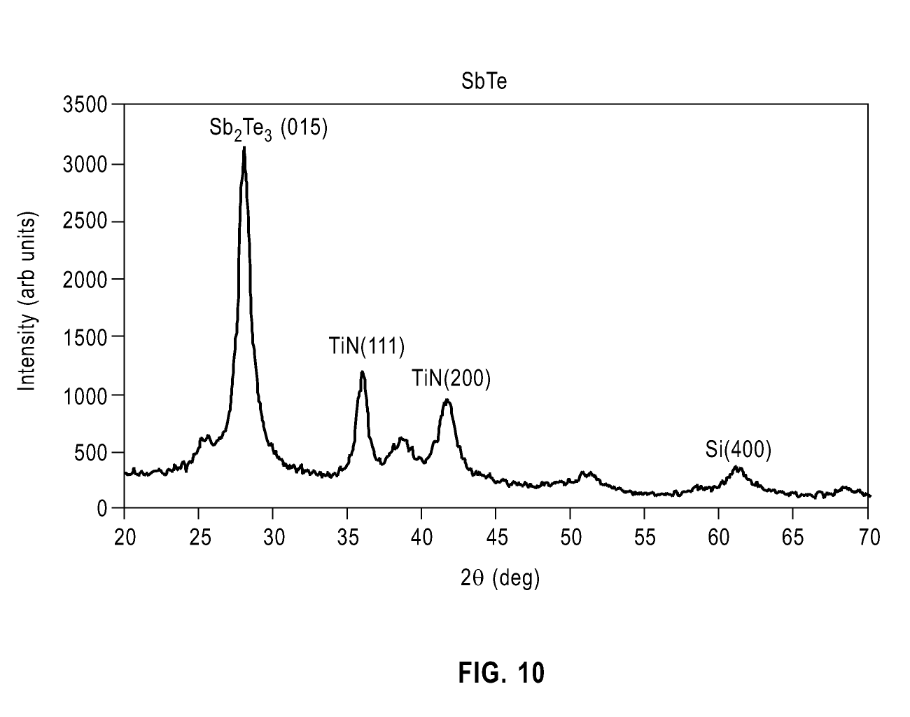

Te deposition and bulk stripping potentials were set at −0.35 V and −0.70V respectively and the Sb deposition potential was set to be −0.20V to obtain the ideal composition. The optimal deposition cycle to form Sb₂Te₃ on TiN is shown in FIG. 9. The ease of Sb deposition suggested TiN to be a good substrate for electrodeposition. The XRD of the as-deposited film (FIG. 10) shows textured crystalline deposit. This is very good when compared to the amorphous as-deposited films obtained from sputtered and even electroplated films.

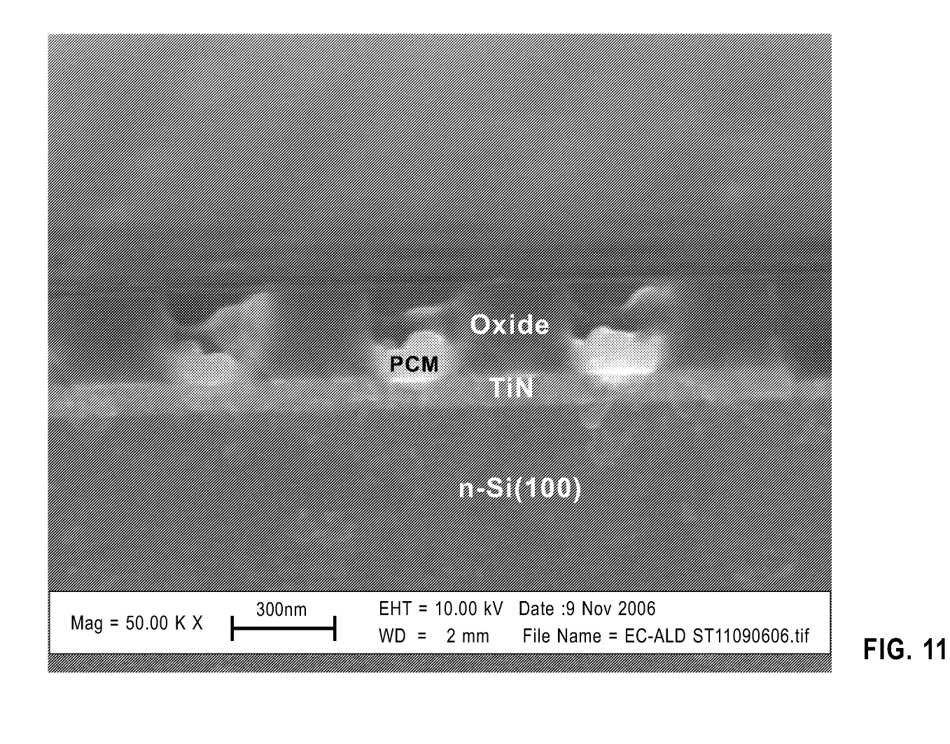

The deposition of Sb₂Te₃ on patterned TiN was studied for selectivity of the deposition process. The patterns consisted of 200 nm pores within silicon oxide with an aspect ratio of 1, laid on a 75 nm layer of PVD TiN layer deposited on an n-Si (100) wafer. After a brief, 1 min DHF (1:100) pretreatment etch, the deposition of Sb₂Te₃ was performed using the same ideal approach for Sb₂Te₃ on TiN using a back contact on n-Si. The SEM image of a 40 cycle deposit is shown in FIG. 11. The deposit shows good selectivity and bottom up fill inside the pores.

### Deposition of InSbTe

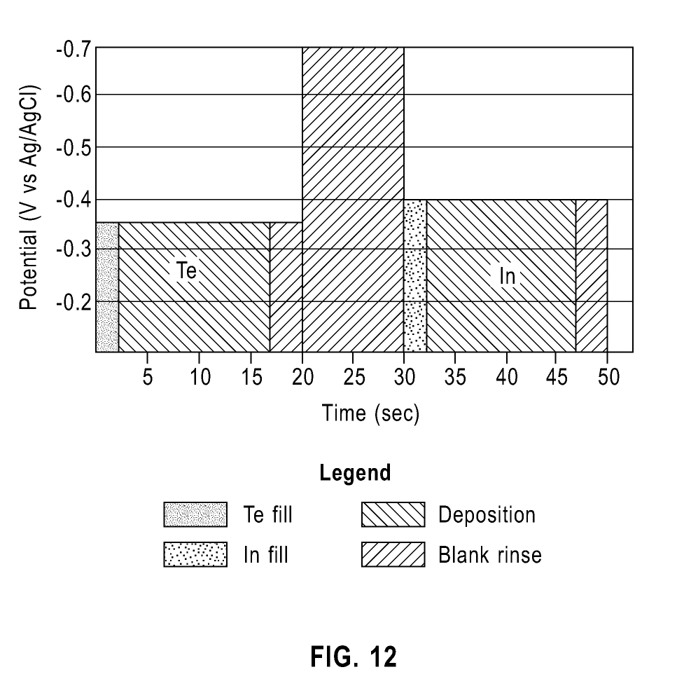

A superlattice approach was taken to form InSbTe by alternating the layers of InTe and SbTe over 10 periods, in which each period consisted of five deposition cycles of InTe and SbTe respectively. The ideal potential for depositing In was found to be −0.40 V. Hence, to deposit InSbTe, the InTe layer was applied by depositing Te first at −0.35 V, then reducing bulk Te at −0.70 V. The In was deposited later at −0.40 V. FIG. 12 shows the cycle for depositing InTe. The Sb₂Te₃ deposition followed the approach described earlier. Another approach, including the deposition step of In in the deposition of Sb₂Te₃ on TiN, is also feasible.

### Deposition of AgSbTe & InAgSbTe

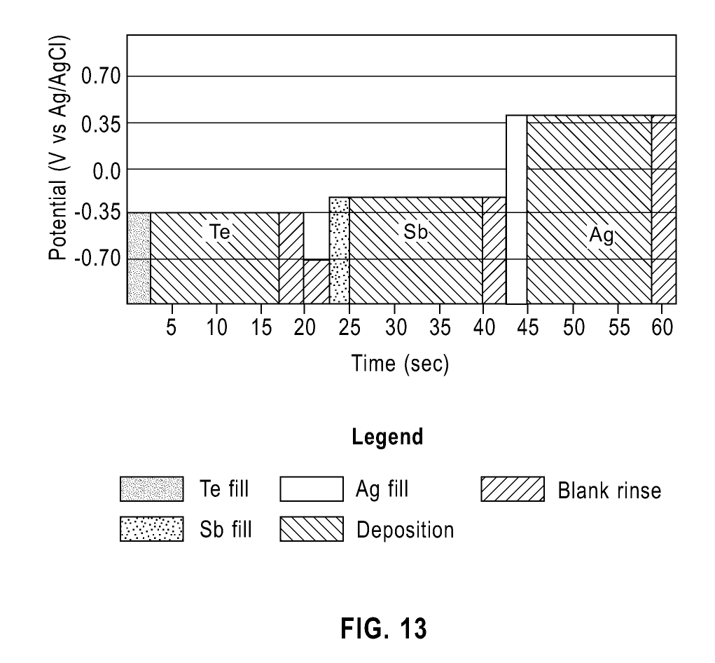

The addition of Ag to Sb₂Te₃ results in a faster crystallization process. Hence, to assess the deposition of Ag first, a cyclic voltammetry was performed on Au electrode in Ag solution. Based on the results the UPD potential of Ag was identified to be 0.43 V. The step of Ag deposition was included in the deposition approach of Sb₂Te₃ deposition on TiN, to form AgSbTe. By combing the deposition conditions of Ag, In, Sb, and Te, InAgSbTe can be deposited in a similar manner. The ALD cycle to deposit AgSbTe is depicted in FIG. 13.

### Incorporation of GeSbTe and GeSb

Generally, Ge deposition is quite difficult using aqueous electrolytes, as once a thin layer of Ge forms on the surface, the further Ge deposition stops. This is probably the reason why non aqueous and ionic electrolytes are explored to electrodeposit Ge. The main objective in this experiment was not to deposit a thick layer of Ge, but to incorporate the UPD of Ge with the Sb₂Te₃ deposition approach to form GeSbTe.

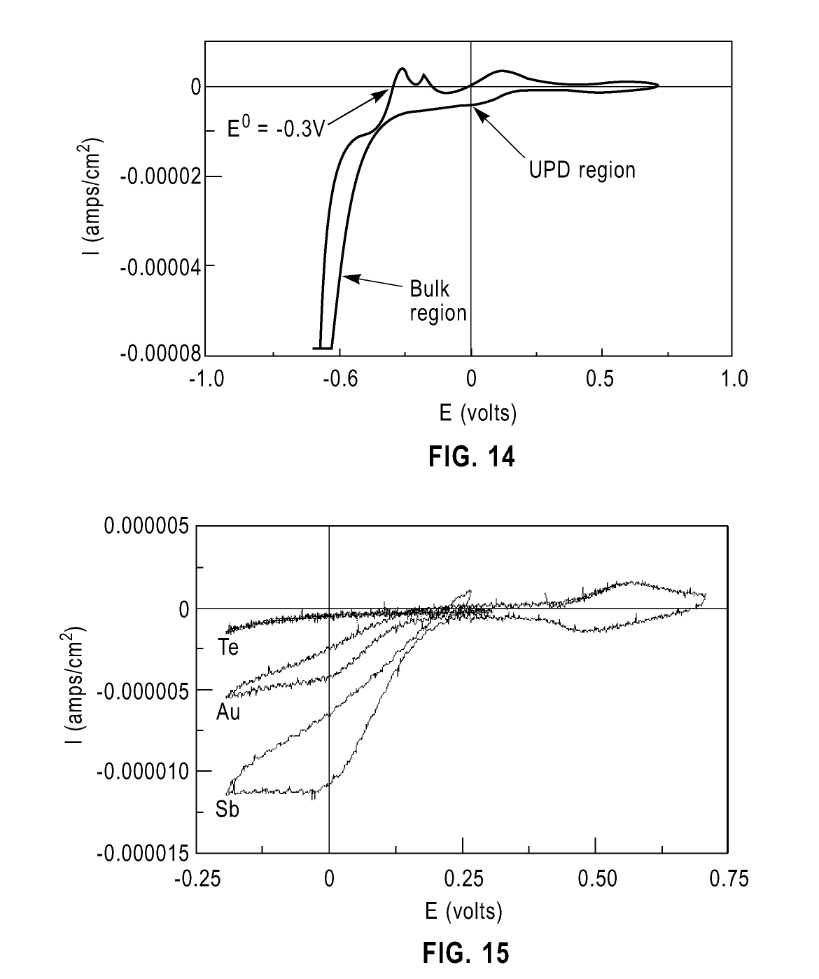

A cyclic voltammetry was performed with a Au electrode in a Ge solution, as shown in FIG. 14. shows the cyclic voltammetry of Ge on a Au substrate. It can be seen that there is a subtle UPD peak for Ge deposition. When reversing the potential sweep toward more positive direction, a Ge stripping peak was observed. Based on the experiments, it was inferred that Ge shows deposition features in aqueous solutions, with a UPD region around −0.20 V. Another experiment was performed to find out the ease of electrodeposition of Ge on Te and Sb surfaces. FIG. 15 indicates that Ge deposits better on a Sb surface, rather than on Te. There is no positive Ge stripping peak for the Te substrate, which indicates that Ge does not deposit on the Te covered substrate. Sb substrate seems to have more Ge deposition compared with Au. Based on these experiments, it was found that GeSbTe is designed to deposit in a sequence of Te, followed by Sb, and then followed by Ge. It is also possible to only deposit a GeSb compound from these results.

Obviously, numerous modifications and variations of the disclosure are possible in light of the above disclosure. It is therefore understood that within the scope of the appended claims, the disclosure may be practiced otherwise than as specifically described herein.

What is claimed is:

1. A method of making a phase change material by electrochemical atomic layer deposition on a substrate, the method comprising:
sequentially electrodepositing at least one atomic monolayer or submonolayer of a first element of a first solution and at least one atomic monolayer or submonolayer of a second element of a second solution on a substrate; and
repeating the sequential electrodepositing until at least one film of a phase change material is formed on the substrate.

2. The method according to claim 1, wherein the phase change material is polycrystalline or single crystalline.

3. The method according to claim 1, wherein the phase change material has a superlattice structure.

4. The method according to claim 1, wherein the first element is selected from the group consisting of germanium (GE), antimony (Sb), Tellurium (Te), indium (In), and silver (Ag).

5. The method according to claim 1, wherein the second element is selected from the group consisting of germanium (GE), antimony (Sb), tellurium (Te), indium (In), and silver (Ag).

6. The method according to claim 1, wherein the first and second elements are selected based on a deposition potential for the elements, and the selected elements are different.

7. The method according to claim 6, wherein the deposition potential for Sb ranges from about −0.3 V to about 0.1 V.

8. The method according to claim 6, wherein the deposition potential for Te ranges from about −0.7 V to about 0.4 V.

9. The method according to claim 6, wherein the deposition potential for Ge ranges from about −0.5 V to about 0.1 V.

10. The method according to claim 6, wherein the deposition potential for In ranges from about −0.5 V to about 0.0 V.

11. The method according to claim 6, wherein the deposition potential for Ag ranges from about 0.1 V to about 0.5 V.

12. The method according to claim 1, wherein the monolayers or submonolayers are electrodeposited at temperatures ranging from about 0° C. to about 90° C.

13. The method according to claim 1, wherein a thickness of each monolayer or submonolayer ranges from about 1 Å to about 10 Å.

14. The method according to claim 1, wherein from about 10 to about 100,000 layers of the phase change material are formed on the substrate.

15. The method according to claim 1, wherein the phase change material is selected from the group consisting of Sb₂Te₃, InSbTe, AgSbTe, GeSb, and GeSbTe, and combinations thereof.

16. The method according to claim 1, wherein the substrate is a conductive metal material.

17. The method according to claim 1, wherein the substrate is a semiconductor.

18. The method according to claim 1, wherein the substrate is an alloy.

19. The method according to claim 1, wherein the substrate is gold.

20. The method according to claim 1, wherein the substrate is titanium nitride.
